(19) United States
(12) Patent Application Publication
(10) Pub. No.: US 2026/0117907 A1
(43) Pub. Date: Apr. 30, 2026

(54) External clamp-type sewer connector system for recreational vehicles

(71) Applicants: JINSUB CHOI, highland village, TX (US); EUNHYUK CHOI, highland village, TX (US)

(72) Inventors: JINSUB CHOI, highland village, TX (US); EUNHYUK CHOI, highland village, TX (US)

(21) Appl. No.: 19/292,476

(22) Filed: Aug. 6, 2025

Related U.S. Application Data
(60) Provisional application No. 63/712,800, filed on Oct. 28, 2024.

(51) Int. Cl. F16L 37/248

(52) U.S. Cl. CPC F16L 37/248; F16L 2201/10

(57) ABSTRACT

An external clamp-type sewer connector system for recreational vehicles (RVs) is provided for use with waste outlet pipes of recreational vehicles (RVs), trailers, mobile homes, yachts, and marine sanitation systems. The connector includes a stainless steel hook ring, a SNAP-LOCK interface for initial engagement, and a pair of adjustable clamp arms that apply compressive force via lever action. A lower portion includes a bayonet-style interface compatible with standard sewer hoses. At least part of the connector body is made of transparent or translucent material, allowing visual confirmation of wastewater flow during operation. This configuration allows tool-free, rotation-free, and secure attachment across diverse outlet types, improving usability, safety, and visual monitoring.

### FIELD OF THE INVENTION

The present invention relates to wastewater discharge connector systems for recreational vehicles (RVs), and more particularly, to an externally mounted clamp-type sewer connector system that allows for secure and tool-free connection to an RV sewer outlet using a hook ring and clamping levers.

### BACKGROUND OF THE INVENTION

Conventional RV sewer connectors primarily rely on bayonet-style fittings that require rotational engagement between the sewer hose and the RV outlet. However, these systems often require significant hand strength, may be incompatible with gloves, and tend to leak if not perfectly aligned. Moreover, due to the circular bayonet rotation mechanism, vibration during travel can lead to loosening or disconnection, posing a risk of contamination or spillage. There is a need for an improved connection system that is compatible with existing bayonet-style hoses but enables more secure, easier, and vibration-resistant engagement without requiring significant torque or tools.

### SUMMARY OF THE INVENTION

The present invention provides a sewer connector system for RVs that includes an external stainless steel hook ring installed on the RV sewer outlet, and a clamp-style connector that attaches to the hook ring via two clamping arms. The connector comprises a transparent or semi-transparent body for visual inspection, a SNAP-LOCK engagement feature—defined herein as a locking interface located inside the connector body that temporarily engages a bayonet lug on the RV sewer outlet to provide primary retention and visual confirmation before full clamping—and adjustable clamp arms with threaded adjusters and locking handles for precise sealing. The invention allows for quick, tool-free, and secure attachment to various RV outlets regardless of minor dimensional differences. This design improves leak prevention, enhances safety, and enables compatibility with standard bayonet-style sewer hoses.

### BRIEF DESCRIPTION OF THE DRAWINGS

FIG. 1A is a side view showing the external clamp-type sewer connector (300) of the present invention prior to being connected to the RV sewer outlet (100). FIG. 1B is a side view showing the external clamp-type sewer connector (300) fully connected and securely fixed to the RV sewer outlet (100).

FIG. 2 is a side view of the RV sewer outlet (100), showing three of four bayonet-style coupling tabs (101a, 101b) formed near the outlet end, with the fourth tab symmetrically positioned on the rear side and not visible from this angle.

FIG. 3A is a perspective view of the stainless steel hook ring (200) of the present invention. FIG. 3B is a top plan view of the stainless steel hook ring (200) of the present invention. FIG. 3C is a side view of the stainless steel hook ring (200) of the present invention. FIG. 3D is a front view of the stainless steel hook ring (200) of the present invention.

FIG. 4 is a side view showing the stainless steel hook ring (200) mounted on the RV sewer outlet (100) of FIG. 2.

FIG. 5A is a perspective view of the external clamp-type RV sewer connector (300) of the present invention. FIG. 5B is a top plan view of the external clamp-type RV sewer connector (300) of the present invention. FIG. 5C is a side view of the external clamp-type RV sewer connector (300) of the present invention. FIG. 5D is a front view of the external clamp-type RV sewer connector (300) of the present invention.

FIG. 6 is a perspective view showing the RV external clamp connector (300) aligned for connection with a commercially available standard sewer hose (400).

FIG. 7 is a side view showing the assembly formed by coupling the RV external clamp connector (300) with the standard sewer hose (400).

FIG. 8 is a side view showing the RV sewer outlet (100), with the stainless steel hook ring (200) installed, aligned for joining to an assembly in which the RV external clamp connector (300) is joined to a commercially available standard sewer hose (400).

FIG. 9 is a side view showing the SNAP-LOCK mechanism, which serves as a primary connection feature, in a locked state.

FIG. 10 is a side view showing the final, fully connected state of the connector assembly of the present invention.

### REFERENCE NUMERALS USED IN THE DRAWINGS

100—RV sewer outlet 101a, 101b—Protrusions (for bayonet connection) 102—Sealing face of the outlet 200—Stainless steel hook ring 201—Alignment protrusion 202—Hook (projection) 203—Ring fastening mechanism 300—External clamp-type connector 301—Clamp arm 302—Threaded adjuster 303—Clamp handle 304—Bayonet lug 305—Lower portion of connector 306—SNAP-LOCK mechanism 307—Hinge 308—Rotational shaft 310-Rubber gasket 400—Standard sewer hose 401—Swivel-type female bayonet coupling

### DETAILED DESCRIPTION

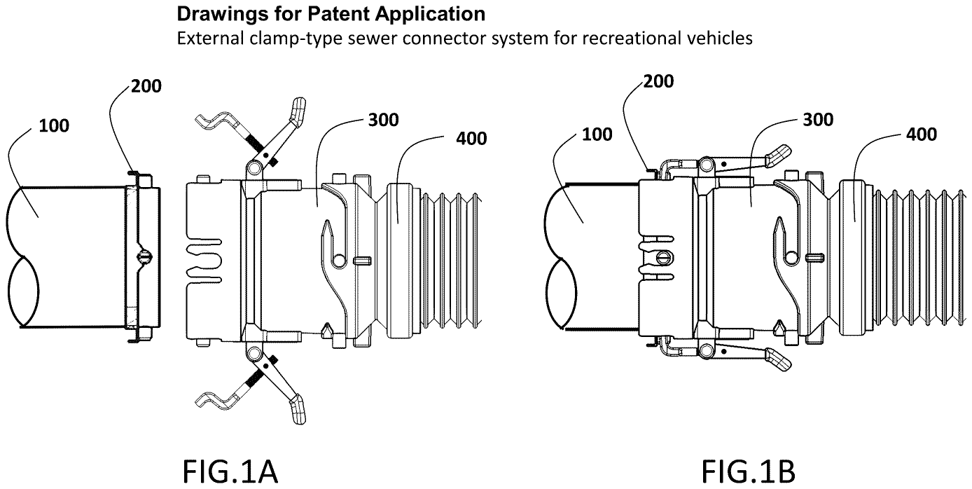

Referring to FIG. 1A, the present invention provides a configuration in which a stainless steel hook ring (200) is mounted and aligned on the RV sewer outlet (100) (hereinafter referred to as “outlet (100)” and “hook ring (200)”). Also shown in FIG. 1A is an RV external clamp connector (300), pre-assembled with a commercially available sewer hose (400) (hereinafter “connector (300)” and “hose (400)”), aligned for connection to the outlet (100).

FIG. 1B illustrates the state in which the connector (300) is fully engaged and securely fastened to the outlet (100). The connector (300) is mounted externally onto the outlet (100) without requiring rotational force or specialized tools. In the final connection state, a sealed and mechanically stable joint is formed, enhancing user convenience and safety.

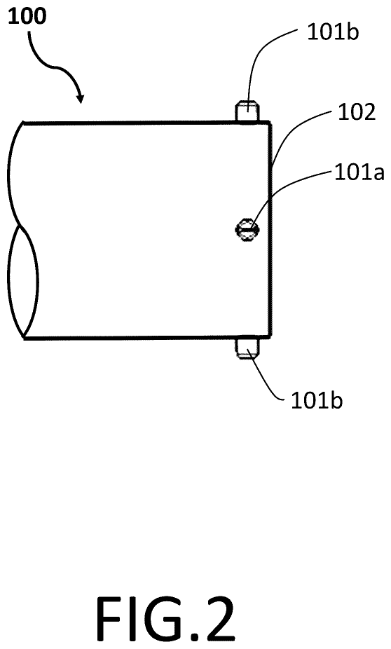

FIG. 2 is a side view of the outlet (100), showing three of the four circumferentially arranged lug-like protrusions (101a, 101b, 101b) formed near the terminal edge. These protrusions (collectively referred to as 101) are typically used to couple with bayonet-style connectors by aligning and rotating the connector. The fourth lug, symmetrically positioned on the rear side of the outlet and not visible in this view, is identical in shape and function to the visible ones.

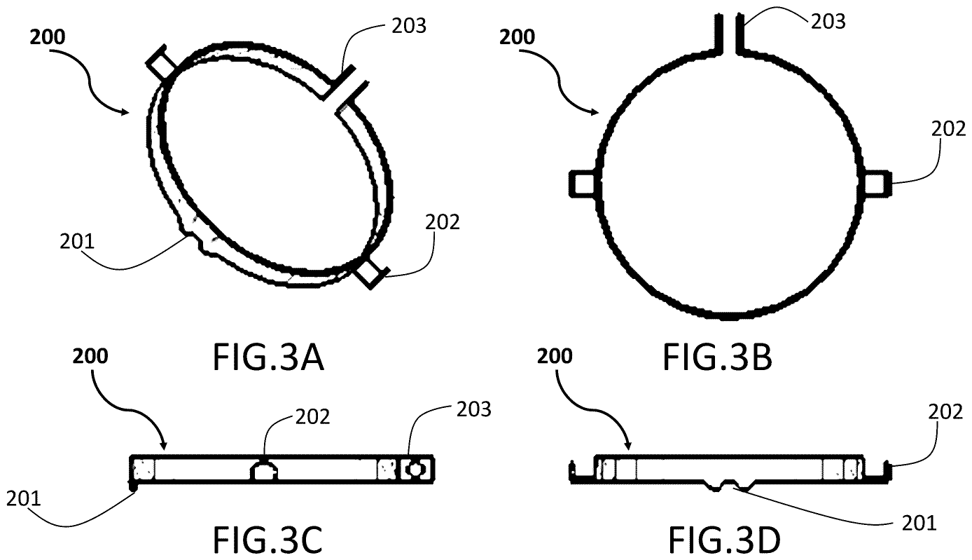

FIGS. 3A to 3D illustrate the hook ring (200) from multiple perspectives. The hook ring (200) is a loop-shaped component mounted on the outer circumferential surface of the outlet (100),
positioned just above the four protrusions (101a and 101b). The hook ring (200) includes two hooks (202) and a semi-circular alignment protrusion (201) for precise centering during installation. It further includes a fastening mechanism (203), which may utilize bolt-and-nut or clamp-type fastening methods, though it is not limited to these.

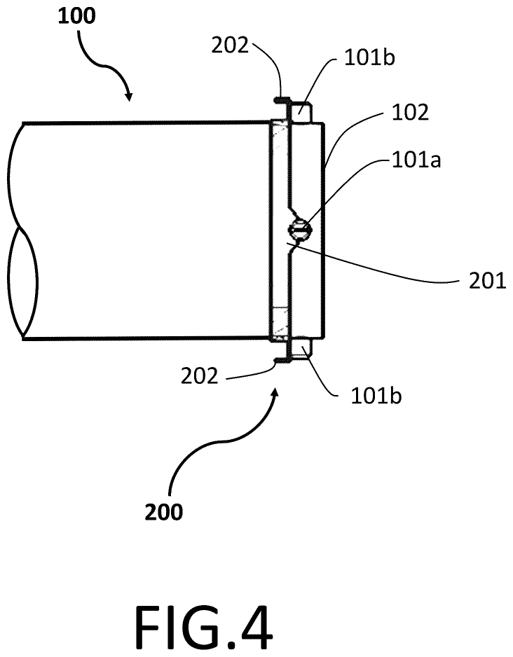

FIG. 4 illustrates the hook ring (200) installed on the outlet (100), with the alignment protrusion (201) positioned directly above a protrusion (101a) designed for engagement with the SNAP-LOCK mechanism. The two hooks (202) are aligned with the upper edges of the outlet protrusions (101b) due to the guidance provided by the alignment protrusion (201). The hook ring (200) is mounted externally without structural modification to the outlet (100) and serves as an anchor point for the connector (300). Its adjustable design allows it to accommodate a range of outlet diameters and tolerances, maintaining secure retention even under vibration or impact.

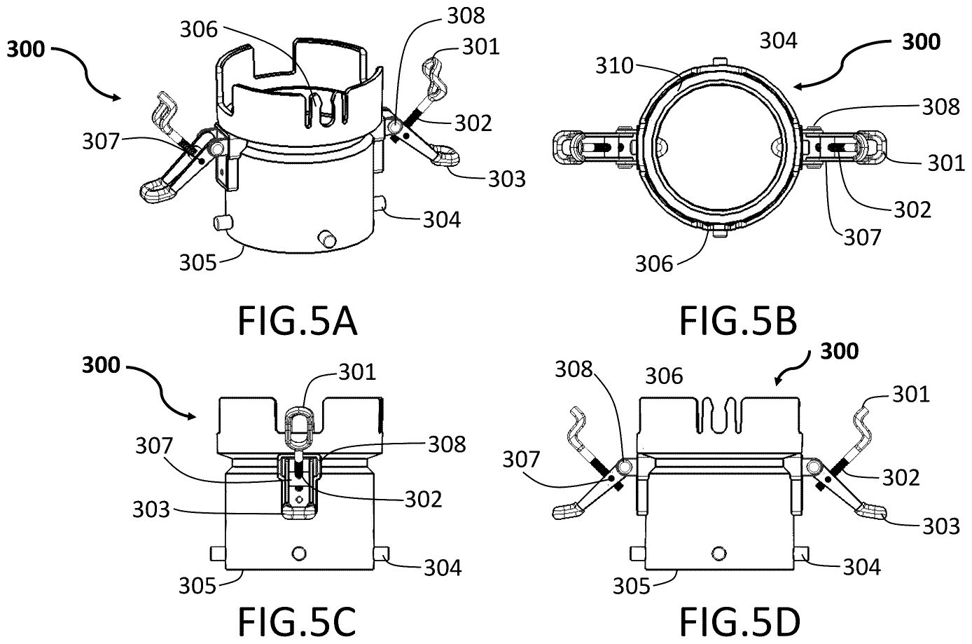

FIGS. 5A to 5D show the connector (300), which is fabricated from transparent or semi-transparent material to enable visual monitoring of wastewater flow during discharge. A SNAP-LOCK mechanism (306) is incorporated for initial engagement. A rubber gasket (310) is installed at the inlet side to ensure a watertight seal against the outlet (100). The connector (300) also includes two opposing clamp arms (301), each connected to a clamp handle (303) via a hinge (307). Threaded adjustment segments (302) are provided on each arm (301) to regulate clamping force and accommodate variations in outlet diameter and tolerance. A rotational shaft (308) connected to each handle (303) enables the opening and locking of the clamp mechanism. The lower portion of the connector (300) includes four bayonet lugs (304) for compatibility with standard bayonet-type sewer hoses.

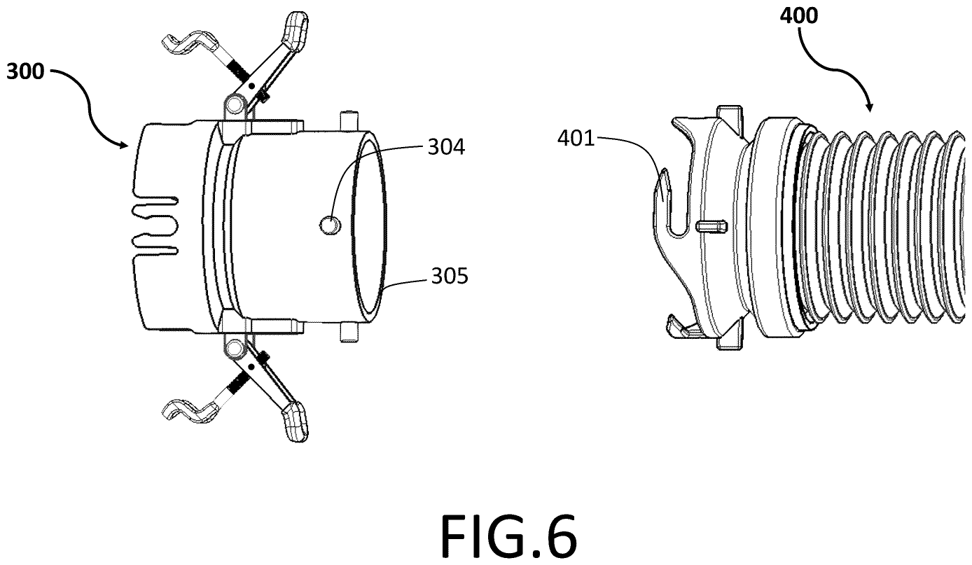

FIG. 6 shows the connector (300) aligned for coupling with the hose (400). The four bayonet lugs (304) of the connector (300) are positioned to engage with a swivel-type female bayonet coupling (401) of the hose (400), prior to connection.

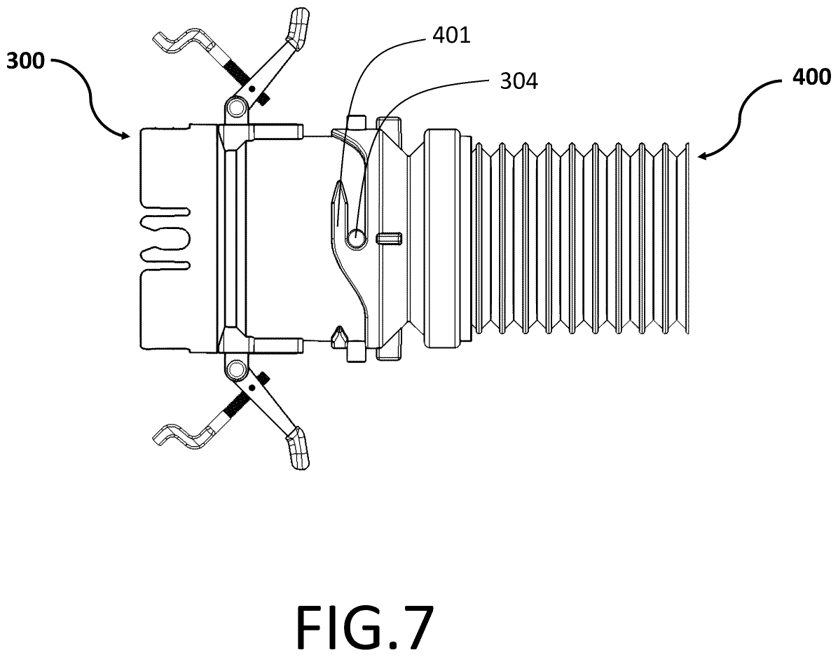

FIG. 7 illustrates the connected state of the connector (300) and hose (400). In this configuration, the lower portion (305) of the connector (300), as identified in FIG. 6, is inserted into the coupling (401) and secured via rotational engagement. A rubber O-ring located within the hose (400) assists in sealing the joint, allowing leak-free fluid transfer. Once connected, the connector (300) and hose (400) form a unified assembly ready for attachment to the outlet (100).

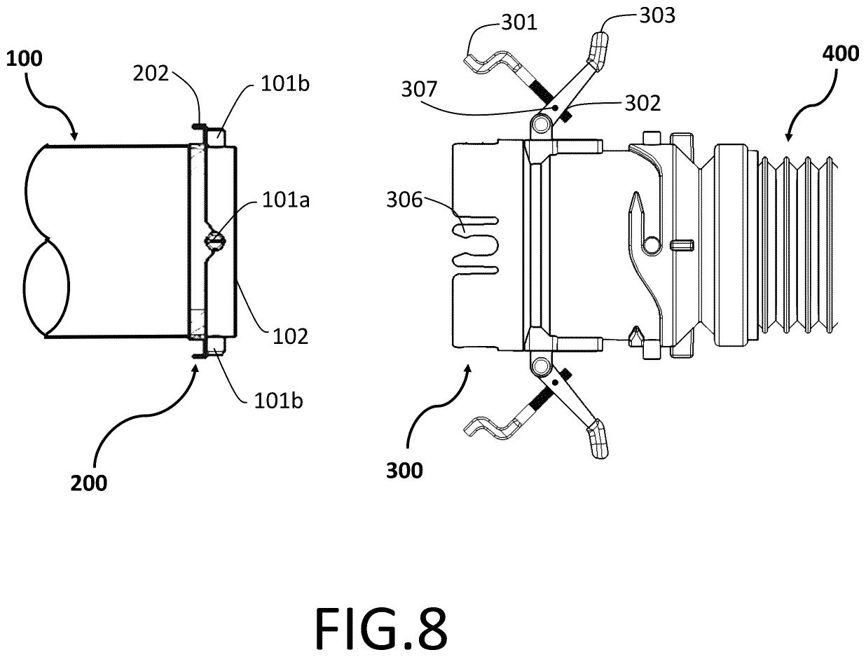

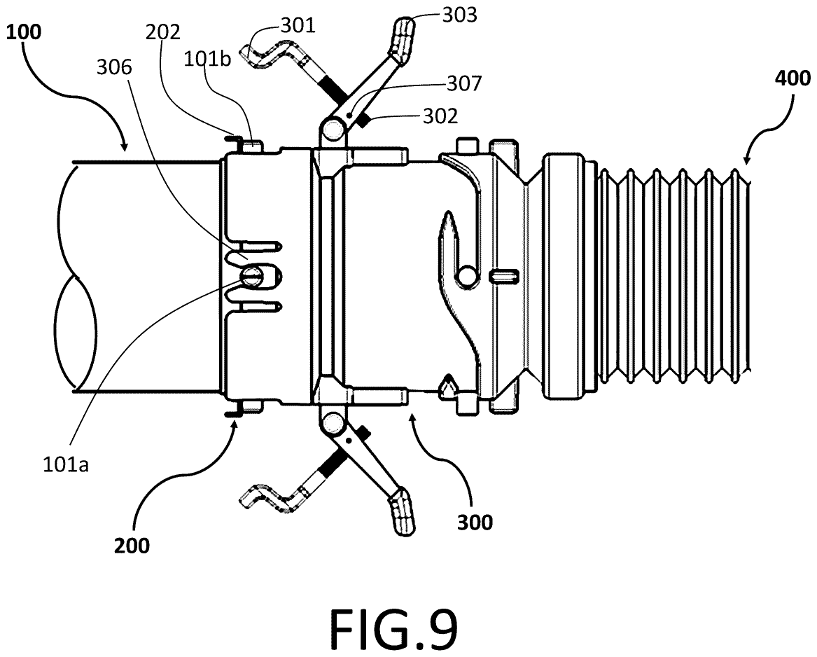

FIG. 8 shows the alignment of the assembly of connector (300) and hose (400) with the outlet (100), to which the hook ring (200) has already been installed. The clamp arms (301) are aligned with the protruding hooks (202) of the hook ring (200). The SNAP-LOCK mechanism (306) of the connector (300) engages with the outlet protrusion (101a), and the post-engagement state is depicted in FIG. 9.

FIG. 9 illustrates the primary engagement state, where the outlet protrusion (101a) is securely positioned inside the SNAP-LOCK mechanism (306). A retention feature ensures the connector
(300) does not become unintentionally disengaged during use. Following this, the user hooks the clamp arms (301) onto the hooks (202) of the hook ring (200) to initiate the final locking step. The clamp arms (301) are precisely aligned with the hook positions, eliminating the need for additional adjustment.

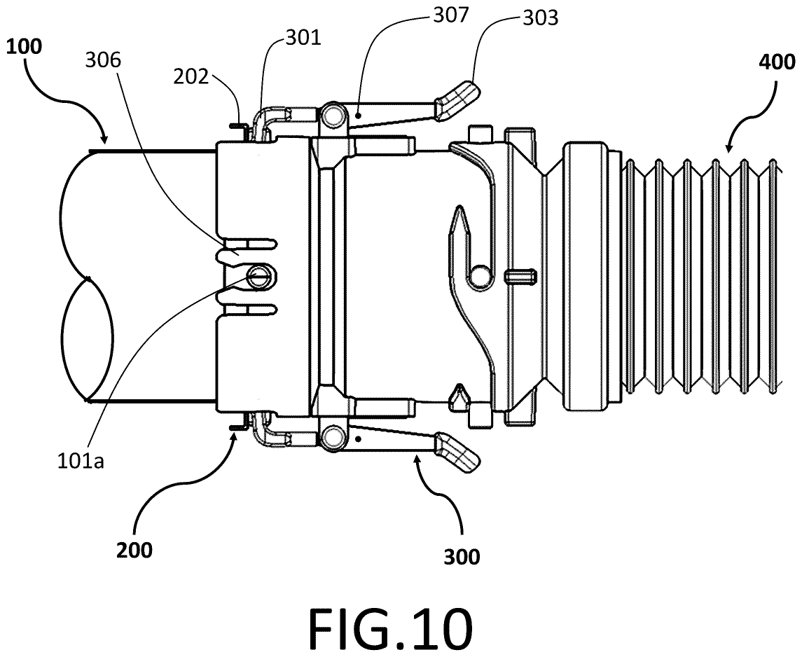

The threaded adjustment sections (302) on the clamp arms (301) enable users to tailor the arm length to fit various outlet sizes, ensuring sufficient compressive force for sealing. With the clamp arms (301) hooked onto the hooks (202), the user pulls down the clamp handles (303), causing the rotational shafts (308) to draw the clamp arms (301) inward, thereby generating compressive sealing force. In this state, the sealing surface (102) of the outlet (100), as referenced in FIG. 8, is pressed firmly against the rubber gasket (310) of the connector (300). Additionally, the protrusion (101a) is further displaced downward into the SNAP-LOCK mechanism (306), as shown in FIG. 10, providing a visual indicator of full engagement.

In the fully fastened condition, the clamp arms (301) exert strong compressive force around the outlet (100) via lever action, forming a robust seal that prevents leakage of wastewater. Once the entire fastening process is complete, the connector (300) remains firmly secured and stable, even under conditions of vibration or external shock.

1. The system of claim 1, wherein at least a portion of the connector body is transparent or semi-transparent to allow visual inspection of fluid flow.

2. The system of claim 1, wherein the hook ring includes an alignment protrusion configured to align the connector body with the axis of the RV sewer outlet.

3. The system of claim 1, wherein the clamp arm includes a threaded adjuster configured to regulate clamping force to accommodate dimensional variations of different RV sewer outlets.

4. The system of claim 1, wherein the SNAP-LOCK mechanism includes a visual indicator confirming secure engagement with the outlet protrusion.

5. The system of claim 1, wherein the clamp arm is hinged to a handle and configured to rotate to engage the hook ring.

6. The system of claim 1, wherein the connector is configured to be attached to the RV sewer outlet without rotational force.

7. The system of claim 1, wherein the connector body includes a rubber gasket at its inlet side, configured to form a watertight seal when compressed against the RV sewer outlet.

8. The system of claim 1, wherein the hook ring is formed of stainless steel.

9. The system of claim 1, wherein the clamp arm includes an over-center lock or latch to prevent loosening once engaged.

10. The system of claim 1, wherein the connector body includes bayonet lugs for attachment to a standard bayonet-style sewer hose.
